(19) United States
(12) Patent Application Publication
(10) Pub. No.: US 2024/0064941 A1
(43) Pub. Date: Feb. 22, 2024

(54) SYSTEMS AND METHODS FOR CONTROLLING TEMPERATURE IN A SERVER

(71) Applicant: Mellanox Technologies, Ltd., Yokneam (IL)

(72) Inventors: Ran Hasson RUSO, Tel Aviv (IL); Alon RUBINSTEIN, Kfar-Yona (IL); Elad MENTOVICH, Tel Aviv (IL); Tahir CADER, Spokane Valley, WA (US); Siddha GANJU, Santa Clara, CA (US)

(73) Assignee: Mellanox Technologies, Ltd., Yokneam (IL)

(21) Appl. No.: 17/892,283

(22) Filed: Aug. 22, 2022

(51) Int. Cl. H05K 7/20; G06N 20/00

(52) U.S. Cl. CPC H05K 7/20836; G06N 20/00

(57) ABSTRACT

A system and method for controlling cooling in a server is provided. The method includes receiving one or more server indicators relating to a task to be executed by at least one component of the server. The method also includes determining an expected cooling demand for the at least one component based on the one or more server indicators. The method further includes adjusting a cooling amount provided by a cooling mechanism based on the expected cooling demand of the at least one component. Various embodiments are described herein.

### TECHNOLOGICAL FIELD

Example embodiments of the present disclosure relate generally to temperature management in servers and, more particularly, to monitoring and controlling temperature of components within a server.

### BACKGROUND

Heat management in data centers is necessary to protect components within the individual servers from overheating. However, different component may have different cooling requirements and therefore it can be difficult to provide efficient cooling to the entire server or data center. Applicant has identified a number of deficiencies and problems associated with data center cooling. Through applied effort, ingenuity, and innovation, many of these identified problems have been solved by developing solutions that are included in embodiments of the present disclosure, many examples of which are described in detail herein.

### BRIEF SUMMARY

In various embodiments, methods, systems, and computer program products are provided for controlling temperature in a server. In an example embodiment, a method for controlling cooling in a server is provided. The method includes receiving one or more server indicators relating to a task to be executed by at least one component of the server. The method also includes determining, via a processor, an expected cooling demand for the at least one component based on the one or more server indicators. The method further includes adjusting a cooling amount provided by a cooling mechanism based on the expected cooling demand of the at least one component.

In various embodiments, at least one of the one or more server indicators is received from a scheduler that indicates one or more upcoming tasks to be executed by the server. In various embodiments, the at least one of the one or more server indicators received from the scheduler indicates an expected usage of at least one of the at least one component for the task. In various embodiments, at least one of the one or more server indicators is received from a switch connected to the server and the at least one of the one or more server indicators includes information relating to traffic routing via the switch.

In various embodiments, at least one of the one or more server indicators is based on a temperature measured by a temperature sensor. In various embodiments, at least two of the one or more server indicators are received from at least two of a scheduler, a switch, or a temperature sensor. In various embodiments, the one or more server indicators include at least one server indicator received from a scheduler, at least one server indicator received from a switch, and at least one server indicator received from a temperature sensor. In such an embodiment, each of the at least one server indicator received from the scheduler, the at least one server indicator received from the switch, and the at least one server indicator received from the temperature sensor is used to determine the expected cooling demand.

In various embodiments, the method includes monitoring a temperature of the at least one component during execution of the task. In such an embodiment, the temperature of the component during the execution is compared to a target temperature to determine whether the cooling amount was correct. In various embodiments, the method includes teaching a training set to determine the expected cooling demand via a machine learning model. In various embodiments, the method includes monitoring the server during execution of the task and updating the training set based on the monitored task execution.

In another example embodiment, a system for controlling cooling in a server is provided. The system includes a server of a data center including at least one component. The system also includes a cooling mechanism for providing a cooling amount to the server. The system further includes a controller in communication with the server and the cooling mechanism. The controller is configured to receive one or more server indicators relating to a task to be executed for at least one component of the server. The controller is also configured to determine, via a processor, an expected cooling demand for the at least one component based on the one or more server indicators. The controller is further configured to adjust a cooling amount provided by the cooling mechanism based on the expected cooling demand of the at least one component.

In various embodiments, at least one of the one or more server indicators is received from a scheduler that indicates one or more upcoming tasks to be executed by the server. In various embodiments, the at least one of the one or more server indicators received from the scheduler indicates an expected usage of at least one of the at least one component for the task.

In various embodiments, the system also includes a switch connected to the server. In such an embodiment, at least one of the one or more server indicators is received from the switch connected to the server and the at least one of the one or more server indicators includes information relating to traffic routing via the switch. In various embodiments, the cooling mechanism is at least one of a liquid cooling mechanism or an air cooling mechanism.

In various embodiments, the system includes a temperature sensor positioned adjacent to the at least one component. In such an embodiment, at least one of the one or more server indicators is based on a temperature measured by the temperature sensor. In various embodiments, at least one of the one or more server indicators indicates a temperature of one or more servers adjacent to the server.

In still another example embodiment, a computer program product for controlling cooling in a server is provided. The computer program product includes at least one non-transitory computer-readable medium having computer-readable program code portions embodied therein. The computer-readable program code portions include an executable portion configured to receive one or more server indicators relating to a task to be executed for at least one component of a server. The computer-readable program code portions also include an executable portion configured to determine, based on the one or more server indicators, an expected cooling demand for the at least one component. The computer-readable program code portions further include an executable portion configured to adjust a cooling amount provided by a cooling mechanism based on the expected cooling demand of the at least one component.

In various embodiments, at least one of the one or more server indicators is received from a scheduler that indicates one or more upcoming tasks to be executed by the server. In various embodiments, the at least one of the one or more server indicators received from the scheduler indicates an expected usage of at least one of the at least one component for the task.

In various embodiments, at least one of the one or more server indicators is received from a switch connected to the server. In such an embodiment, the at least one of the one or more server indicators includes information relating to traffic routing via the switch.

In various embodiments, at least one of the one or more server indicators is based on a temperature measured by a temperature sensor. In various embodiments, the computer-readable program code portions also include an executable portion configured to monitor a temperature of the at least one component during execution of the task. In such an embodiment, the temperature of the component during the execution is compared to a target temperature to determine whether the cooling amount was correct.

In various embodiments, the computer-readable program code portions also include an executable portion configured to teach a training set to determine the expected cooling demand via a machine learning model. In various embodiments, the computer-readable program code portions also include an executable portion configured to monitor the server during execution of the task and updating a training set based on the monitored task execution.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIG. 1 provides a block diagram illustrating a system environment for controlling cooling in a server, in accordance with various embodiments of the present disclosure;

FIG. 2 is an exemplary block diagram of a cooling control device, in accordance with various embodiments of the present disclosure; and

FIG. 3 illustrates a flowchart of an example method for controlling cooling in a server, in accordance with various embodiments of the present disclosure.

### DETAILED DESCRIPTION

### Overview

Servers in a data center during operation produce heat and therefore require cooling in order to function properly. However, the individual components of a server have different workloads and acceptable temperature ranges, resulting in different cooling needs. Current cooling functionality provides cooling at a server level based on the hottest component in the server. This approach is inefficient, as other components of the server may not require as much cooling. Therefore, various embodiments of the present disclosure allow for cooling control at the component level. Additionally, current cooling is either passive or reactive cooling. Passive cooling is cooling based on the design of the server, and reactive cooling is cooling in response to a change in temperature. The present disclosure provides for proactive cooling, which allows the cooling mechanism to ramp up cooling before task execution to improve efficiency.

Various embodiments of the present disclosure provide for a system to control cooling in a server. The system uses server indicators received from temperature sensor(s), task schedulers, and/or traffic switch(es) to determine the amount of cooling needed (e.g., based on an expected cooling demand) for the server, and more specifically for the individual components of the server. The determination of the expected cooling demand can be completed before a task is executed by the server, allowing the cooling mechanism to be increased in anticipation of increased need before the task execution begins. This eliminates inefficiencies caused by lags in adjusting the cooling amount reactively (e.g., the adjustment to the cooling amount may not happen instantly, but rather may be associated with a certain response time). Upon determining the expected cooling demand and adjusting the cooling amount, the system may monitor the server (e.g., the temperature) during the execution of the task and compare the actual results (e.g., operating temperature, system strain, and/or the like) of the execution to the expected results. The system may use a machine learning model to determine the expected cooling demand, and the machine learning model may be updated upon subsequent task executions.

Embodiments of the present disclosure will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. Furthermore, as would be evident to one of ordinary skill in the art in light of the present disclosure, the terms “substantially” and “approximately” indicate that the referenced element or associated description is accurate to within applicable engineering tolerances.

### Example Network Configuration

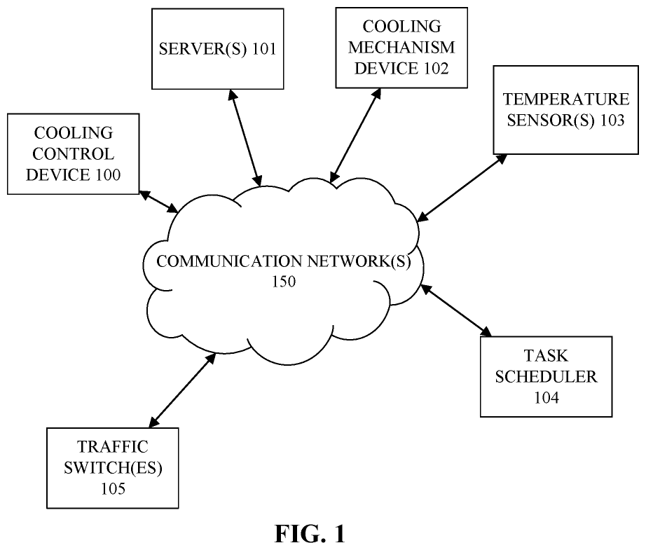

FIG. 1 provides a block diagram illustrating a system environment for controlling cooling in one or more servers. As illustrated in FIG. 1, the system environment includes a cooling control device 100, one or more server(s) 101, and a cooling mechanism device 102. The components of the system (e.g., the cooling control device 100, the one or more server(s) 101, and/or the cooling mechanism device 102) may be in communication with each other and with other components of the system via a communication network 150. For example, the cooling control device 100 may receive server indicators from at least one of one or more temperature sensors 103, a task scheduler 104, and/or one or more traffic switches 105 via the communication network 150.

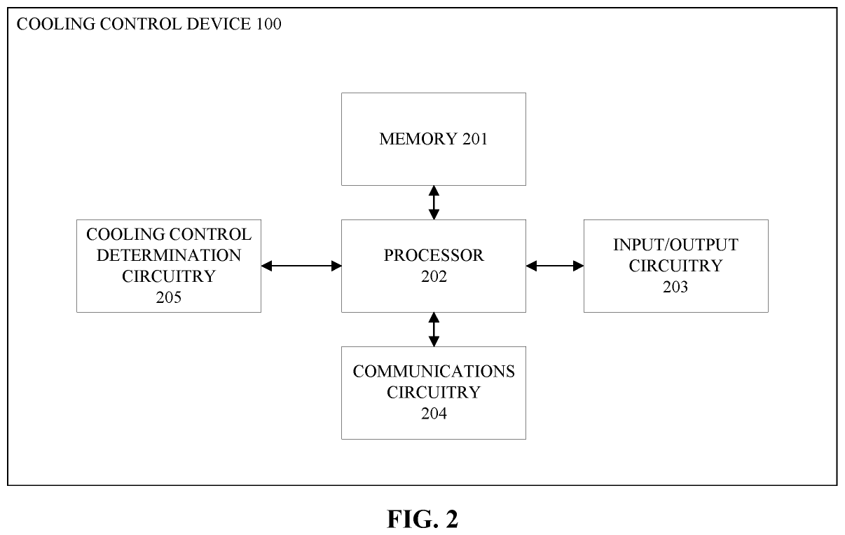

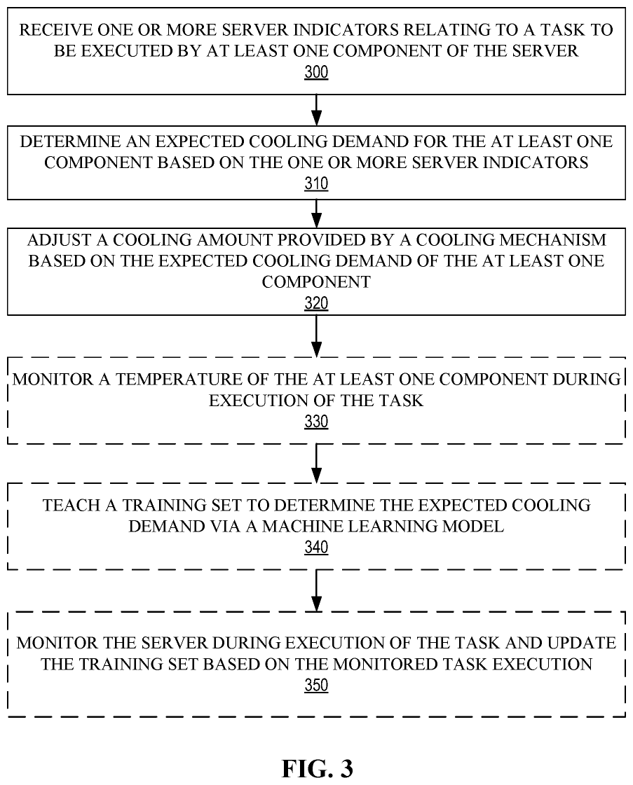

As discussed herein, the cooling control device 100 may be configured to control the cooling amount provided by the cooling mechanism device 102 to one or more components of the one or more servers 101. As discussed in more detail below with reference to FIGS. 2 and 3, the cooling control device 100 may receive one or more server indicators from the one or more temperature sensors 103, the task scheduler 104, and/or the one or more traffic switches 105. Based on the server indicators, the cooling control device 100 may determine an expected cooling demand and then adjust the cooling amount provided (e.g., cause a transmission to the cooling mechanism device 102 to adjust the cooling amount) based on the expected cooling demand.

Each of the server(s) 101 has individual components that have different workloads and therefore different temperature/cooling requirements during operation of a task. Example components of a server 101 include graphics processing units (GPU), central processing units (CPU), data processing units (DPU), switches, optical components, and/or the like.

The server(s) 101 may each have one or more temperature sensors 103. The temperature sensor(s) 103 may be located adjacent to or integral with the server 101. The temperature sensor(s) 103 may monitor the temperature at the server level or at a component level. For example, individual temperature sensors may be positioned adjacent to individual components. The cooling control device 100 may receive a server indicator (e.g., the temperatures recorded) via the temperature sensor(s) 103. The server indicator received from the given temperature sensor may also include additional information, such as information relating to the location of the temperature sensor, the time of the temperature recording, and/or a change in the temperature from a previous recording or baseline temperature.

The server(s) 101 may have a task scheduler 104 that assigns tasks to given servers 101. For example, a task scheduler 104 may determine which servers from a plurality of servers 101 are available to execute a given task and may assign the task to a particular available server. The task scheduler 104 in this example, therefore, has information relating to the future tasks to be executed by a given server 101. The task scheduler 104 may transmit one or more server indicators relating to the upcoming tasks to be completed by a given server 101 to the cooling control device 100. In various embodiments, the task scheduler 104 also has information relating to an expected usage for one or more components of a server due to execution of a given task. For example, the expected usage for one or more components may be based on historical data from previous execution of the same or similar task. The expected usage may be the defined as an amount of total capacity a given component has available and/or the expected heat generated by the component over the period of time in which the task is being executed. The task scheduler 104 may include expected usage at the component level of a server (e.g., task A may be more GPU intensive, while task B is more CPU intensive), allowing for independent cooling adjustments across different components of the server. Additionally, tasks scheduled for adjacent servers 101 within a data center may also be considered in determining the expected cooling amount. For example, the heat from a second server adjacent to a first server caused by an intensive task can also increase the temperature of the first server due to proximity of the second server to the first server. As discussed herein, the system may use machine learning to determine expected usage using historical data as the training set.

In various embodiments, the system may include one or more traffic switches 105 in communication with network devices via a network 150. The traffic switch(es) 105 may be configured to receive and facilitate the transmission of tasks to a given server 101. As such, the traffic switch(es) 105 may receive information relating to tasks before the task is received by the server 101. In various embodiments, the cooling control device 100 may receive one or more server indicators from the traffic switch(es) 105 that indicate upcoming tasks for a given server 101. The server indicators received from a traffic switch 105 may include the task being routed by the switch, the amount of data associated with the task being routed, and/or the like.

The cooling mechanism device 102 may be configured to provide a cooling amount to the server(s) 101. The cooling mechanism device 102 may include one or more cooling mechanisms configured to provide cooling to server(s) 101 and/or components of the server(s) 101. The cooling mechanism device 102 may employ various cooling methods, such as air cooling (e.g., where the cooling mechanism device may comprise one or more fans) and/or liquid cooling. The cooling mechanism device 102 may be configured to adjust the cooling amount based on information received from the cooling control device 100. For example, in an example in which the cooling mechanism device 102 includes a fan, the fan may be sped up in response to an increase in cooling demand to provide more cooling amount. The cooling mechanism device 102 may have multiple individual cooling components used to target individual servers within a data center and/or individual components within a server 101. For example, the GPU or CPU may typically require more cooling than other components and, therefore, a specific cooling component may be provided that targets the GPU or CPU. Additionally, as different tasks are intensive on different components, the individual cooling components may be independently adjustable to efficiently cool the server.

The cooling control device 100, the server(s) 101, the cooling mechanism device 102, the temperature sensor(s) 103, the task scheduler 104, and/or the traffic switch(es) 105 may be in network communication across the system environment through the network 150. The network 150 may include a local area network (LAN), a wide area network (WAN), and/or a global area network (GAN). The network 150 may provide for wireline, wireless, or a combination of wireline and wireless communication between devices in the network. In one embodiment, the network 150 includes the Internet. The network 150 may include one or more LoRa gateways (e.g., LoRaWAN gateway(s)) connecting the network. In general, the cooling control device 100 may be configured to communicate information or instructions with the server(s) 101 and/or the cooling mechanism device 102 across the network 150. While the cooling control device 100, the server(s) 101, and the cooling mechanism device 102 are illustrated as separate components communicating via network 150, one or more of the components discussed here may be incorporated as part of a single component or module and/or may be carried out via the same system (e.g., a single system may include the cooling control device 100 and the cooling mechanism device 102).

### Example Cooling Control Device for Server

FIG. 2 shows a schematic block diagram of example circuitry, some or all of which may be included in a cooling control device 100. In accordance with some example embodiments, the cooling control device 100 may include a memory 201, processor 202, input/output circuitry 203, and/or communications circuitry 204. Moreover, in some embodiments, cooling control determination circuitry 205 may also or instead be included in the cooling control device 100. For example, where cooling control determination circuitry 205 is included in the cooling control device 100, the cooling control determination circuitry 205 may be configured to facilitate the functionality discussed herein regarding monitoring and/or controlling the cooling provided to one or more servers (e.g., via the cooling mechanism device 102). An apparatus, such as the cooling control device 100, may be configured, using one or more of circuitry 201-205, to execute the operations described above with respect to FIG. 1 and below in connection with FIG. 3.

Although the term “circuitry” as used herein with respect to components 201-205 is described in some cases using functional language, it should be understood that the particular implementations necessarily include the use of particular hardware configured to perform the functions associated with the respective circuitry as described herein. It should also be understood that certain of these components 201-205 may include similar or common hardware. For example, two sets of circuitries may both leverage use of the same processor, network interface, storage medium, or the like to perform their associated functions, such that duplicate hardware is not required for each set of circuitries. It will be understood in this regard that some of the components described in connection with the cooling control device 100 may be housed within this device, while other components are housed within another of these devices, or by yet another device not expressly illustrated in FIG. 1 (e.g., the cooling control device 100 may be the same device as the server 101 and/or the cooling mechanism device 102).

While the term “circuitry” should be understood broadly to include hardware, in some embodiments, the term “circuitry” also includes software for configuring the hardware. For example, in some embodiments, “circuitry” may include processing circuitry, storage media, network interfaces, input/output devices, and the like. In some embodiments, other elements of the cooling control device 100 may provide or supplement the functionality of particular circuitry. For example, the processor 202 may provide processing functionality, the memory 201 may provide storage functionality, the communications circuitry 204 may provide network interface functionality, and the like.

In some embodiments, the processor 202 (and/or co-processor or any other processing circuitry assisting or otherwise associated with the processor) may be in communication with the memory 201 via a bus for passing information among components of, for example, cooling control device 100. The memory 201 may be non-transitory and may include, for example, one or more volatile and/or non-volatile memories, or some combination thereof. In other words, for example, the memory 201 may be an electronic storage device (e.g., a non-transitory computer readable storage medium). The memory 201 may be configured to store information, data, content, applications, instructions, or the like, for enabling an apparatus, e.g., the cooling control device 100, to carry out various functions in accordance with example embodiments of the present disclosure.

Although illustrated in FIG. 2 as a single memory, the memory 201 may comprise a plurality of memory components. The plurality of memory components may be embodied on a single computing device or distributed across a plurality of computing devices. In various embodiments, the memory 201 may comprise, for example, a hard disk, random access memory, cache memory, flash memory, a compact disc read only memory (CD-ROM), digital versatile disc read only memory (DVD-ROM), an optical disc, circuitry configured to store information, or some combination thereof. Memory 201 may be configured to store information, data, applications, instructions, or the like for enabling the cooling control device 100 to carry out various functions in accordance with example embodiments discussed herein. For example, in at least some embodiments, the memory 201 is configured to buffer data for processing by the processor 202. Additionally or alternatively, in at least some embodiments, the memory 201 is configured to store program instructions for execution by the processor 202. The memory 201 may store information in the form of static and/or dynamic information. This stored information may be stored and/or used by the cooling control device 100 during the course of performing its functionalities.

The processor 202 may be embodied in a number of different ways and may, for example, include one or more processing devices configured to perform independently. Additionally, or alternatively, the processor 202 may include one or more processors configured in tandem via a bus to enable independent execution of instructions, pipelining, and/or multithreading. The processor 202 may, for example, be embodied as various means including one or more microprocessors with accompanying digital signal processor(s), one or more processor(s) without an accompanying digital signal processor, one or more coprocessors, one or more multi-core processors, one or more controllers, processing circuitry, one or more computers, various other processing elements including integrated circuits such as, for example, an ASIC (application specific integrated circuit) or FPGA (field programmable gate array), or some combination thereof. The use of the term “processing circuitry” may be understood to include a single core processor, a multi-core processor, multiple processors internal to the apparatus, and/or remote or “cloud” processors. Accordingly, although illustrated in FIG. 2 as a single processor, in some embodiments, the processor 202 comprises a plurality of processors. The plurality of processors may be embodied on a single computing device or may be distributed across a plurality of such devices collectively configured to function as the cooling control device 100. The plurality of processors may be in operative communication with each other and may be collectively configured to perform one or more functionalities of the cooling control device 100 as described herein.

In an example embodiment, processor 202 is configured to execute instructions stored in the memory 201 or otherwise accessible to the processor 202. Alternatively, or additionally, the processor 202 may be configured to execute hard-coded functionality. As such, whether configured by hardware or software methods, or by a combination thereof, the processor 202 may represent an entity (e.g., physically embodied in circuitry) capable of performing operations according to an embodiment of the present disclosure while configured accordingly. Alternatively, as another example, when the processor 202 is embodied as an executor of software instructions, the instructions may specifically configure processor 202 to perform one or more algorithms and/or operations described herein when the instructions are executed. For example, these instructions, when executed by processor 202, may cause the cooling control device 100 to perform one or more of the functionalities of cooling control device 100 as described herein.

In some embodiments, the cooling control device 100 further includes input/output circuitry 203 that may, in turn, be in communication with the processor 202 to provide an audible, visual, mechanical, or other output and/or, in some embodiments, to receive an indication of an input from a user or another source. In that sense, the input/output circuitry 203 may include means for performing analog-to-digital and/or digital-to-analog data conversions. The input/output circuitry 203 may include support, for example, for a display, touchscreen, keyboard, mouse, image capturing device (e.g., a camera), microphone, and/or other input/output mechanisms. Input/output circuitry 203 may comprise a user interface and may comprise a web user interface, a mobile application, a kiosk, or the like. The input/output device may be used by a user to view and/or adjust expected cooling amounts provided by the system (e.g., a user may want to provide more cooling than necessary to a specific component to protect the component).

The processor 202 and/or user interface circuitry comprising the processor 202 may be configured to control one or more functions of a display or one or more user interface elements through computer-program instructions (e.g., software and/or firmware) stored on a memory accessible to the processor 202 (e.g., the memory 201, and/or the like). In some embodiments, aspects of input/output circuitry 203 may be reduced as compared to embodiments where the cooling control device 100 may be implemented as an end-user machine or other type of device designed for complex user interactions. In some embodiments (like other components discussed herein), the input/output circuitry 203 may even be eliminated from cooling control device 100. The input/output circuitry 203 may be in communication with memory 201, communications circuitry 204, and/or any other component(s), such as via a bus. Although more than one input/output circuitry and/or other component can be included in the cooling control device 100, only one is shown in FIG. 2 to avoid overcomplicating the disclosure (e.g., as with the other components discussed herein).

The communications circuitry 204, in some embodiments, includes any means, such as a device or circuitry embodied in either hardware, software, firmware or a combination of hardware, software, and/or firmware, that is configured to receive and/or transmit data from/to a network and/or any other device, circuitry, or module in communication with the cooling control device 100. In this regard, the communications circuitry 204 may include, for example, a network interface for enabling communications with a wired or wireless communication network. For example, in some embodiments, communications circuitry 204 is configured to receive and/or transmit any data that may be stored by the memory 201 using any protocol that may be used for communications between computing devices. For example, the communications circuitry 204 may include one or more network interface cards, antennae, transmitters, receivers, buses, switches, routers, modems, and supporting hardware and/or software, and/or firmware/software, or any other device suitable for enabling communications via a network. Additionally or alternatively, in some embodiments, the communications circuitry 204 includes circuitry for interacting with the antenna(s) to cause transmission of signals via the antenna(e) or to handle receipt of signals received via the antenna(e). These signals may be transmitted by the cooling control device 100 using any of a number of wireless personal area network (PAN) technologies, such as Bluetooth® v1.0 through v5.0, Bluetooth Low Energy (BLE), infrared wireless (e.g., IrDA), ultra-wideband (UWB), induction wireless transmission, or the like. In addition, it should be understood that these signals may be transmitted using Wi-Fi, Near Field Communications (NFC), Worldwide Interoperability for Microwave Access (WiMAX) or other proximity-based communications protocols. The communications circuitry 204 may additionally or alternatively be in communication with the memory 201, the input/output circuitry 203, and/or any other component of cooling control device 100, such as via a bus.

The communication circuitry 204 of the cooling control device 100 may also be configured to receive and transmit information (e.g., server indicators relating to a task) with the temperature sensor(s) 103, the task scheduler 104, and/or the traffic switch(es) 105 of the one or more server(s) 101. As described above, the server indicators received may be used in the determination of appropriate cooling of the server. Examples of server indicators may include the temperature of one or more components of the server, expected usage of one or more components of the server based on an upcoming task, and/or current usage of one or more components of the server. Additionally, the cooling control device 100 may be in communication with the cooling mechanism device 102 to cause the cooling mechanism device 102 to provide a cooling amount based on the expected demand of one or more components.

In some embodiments, the cooling control device 100 includes hardware, software, firmware, and/or a combination of such components, configured to support various aspects of controlling cooling in the server(s) as described herein (e.g., receiving one or more server indicators relating to a task to be executed by at least one component of the server, determining an expected cooling demand for the at least one component based on the one or more server indicators, and adjusting a cooling amount provided by a cooling mechanism based on the expected cooling demand of the at least one component). It should be appreciated that in some embodiments, the cooling control determination circuitry 205 performs one or more of such exemplary actions in combination with another set of circuitry of the cooling control device 100, such as one or more of the memory 201, processor 202, input/output circuitry 203, and communications circuitry 204.

For example, in some embodiments, the cooling control determination circuitry 205 utilizes processing circuitry, such as the processor 202 and/or the like, to perform one or more of its corresponding operations. In a further example, and in some embodiments, some or all of the functionality of the cooling control determination circuitry 205 may be performed by processor 202. In this regard, some or all of the example processes and algorithms discussed herein can be performed by at least one processor 202 and/or cooling control determination circuitry 205. It should also be appreciated that, in some embodiments, cooling control determination circuitry 205 may include a separate processor, specially configured field programmable gate array (FPGA), or application specific interface circuit (ASIC) to perform its corresponding functions.

Additionally or alternatively, in some embodiments, the cooling control determination circuitry 205 uses the memory 201 to store collected information. For example, in some implementations, the cooling control determination circuitry 205 includes hardware, software, firmware, and/or a combination thereof, that interacts with the memory 201 to send, retrieve, update, and/or store data. Additionally or alternatively, in some embodiments, the cooling control determination circuitry 205 uses the input/output circuitry 203 to facilitate the provision of user output (e.g., causing rendering of one or more user interface(s) such as information relating to cooling), and/or to receive user input (e.g., user clicks, user taps, keyboard interactions, user gesture, and/or the like that may adjust or otherwise affect cooling parameters). Additionally or alternatively, in some embodiments, the cooling control determination circuitry 205 uses the communications circuitry 204 to initiate transmissions to another computing device, receive transmissions from another computing device, communicate signals between the various sets of circuitry as depicted, and/or the like.

Accordingly, non-transitory computer readable storage media can be configured to store firmware, one or more application programs, and/or other software, which include instructions and/or other computer-readable program code portions that can be executed to direct operation of the cooling control device 100 to implement various operations, including the examples shown herein. As such, a series of computer-readable program code portions may be embodied in one or more computer-program products and can be used, with a device, cooling control device 100, database, and/or other programmable apparatus, to produce the machine-implemented processes discussed herein. It is also noted that all or some of the information discussed herein can be based on data that is received, generated and/or maintained by one or more components of the cooling control device 100. In some embodiments, one or more external systems (such as a remote cloud computing and/or data storage system) may also be leveraged to provide at least some of the functionality discussed herein.

### Example Method of Controlling Cooling in a Server

FIG. 3 illustrates an example method of controlling cooling in a server. The method may be carried out by embodiments of the system discussed herein (e.g., the cooling control device 100, the server(s) 101, and/or the cooling mechanism device 102). An example system may include at least one non-transitory storage device and at least one processing device coupled to the at least one non-transitory storage device, as described above. In such an embodiment, the at least one processing device is configured to carry out the method discussed herein.

Referring now to Block 300 of FIG. 3, the method includes receiving one or more server indicators relating to a task to be executed by at least one component of the server. In the depicted embodiment, the cooling control device 100 receives the one or more server indicators from the temperature sensor(s) 103, the task scheduler 104, and/or the traffic switch(es) 105. In various embodiments, the cooling control device 100 receives server indicators from a plurality of the temperature sensor(s) 103, the task scheduler 104, and the traffic switch(es) 105.

In an instance in which at least one of the one or more server indicators is received from a task scheduler 104, the server indicator received from the task scheduler 104 indicates one or more upcoming tasks to be executed by the given server 101. The at least one server indicators received from the scheduler may indicate an expected usage of at least one of the at least one component for the task. The expected usage may be based on historical usage information. In such an instance, a machine learning model may be used to determine the expected usage of one or more components of the server, as discussed below in reference to Block 340 of FIG. 3.

In an instance in which at least one of the one or more server indicators is received from a traffic switch 105 connected to the server, the at least one of the one or more server indicators includes information relating to traffic routing via the traffic switch 105. The server indicator information provided by the traffic switch 105 may include task information, data volume, and/or the like.

In an instance in which at least one of the one or more server indicators is received from one or more temperature sensors 103, the server indicator includes one or more temperatures measured by a temperature sensor. The server indicator received may correspond to the given server 101 itself or components of the server 101 (e.g., the temperature sensor may be positioned adjacent to the GPU of the server and may provide information specific to the GPU). Additionally, one or more temperature sensors 103 may also be located on adjacent servers 101, such that the cooling control device 100 receives a server indicator indicating the temperature of an adjacent server (e.g., the temperature of adjacent servers can affect server temperature). Additionally, temperatures measured by multiple temperature sensors located in or near a server 101 may be used to determine the temperature of one or more components of the given server 101. For example, the temperature of a component of the server may be determined based on the average of the temperature of surrounding components in the server.

Referring now to Block 310 of FIG. 3, the method includes determining an expected cooling demand for the at least one component based on the one or more server indicators. Based on the one or more server indicators, the cooling control device 100 can determine the expected cooling demand for the server. The expected cooling demand may be determined at the server level or at the component level.

The expected cooling demand may be determined based on a combination of the server indicators received from the temperature sensor(s) 103, the task scheduler 104, and/or the traffic switch(es) 105. For example, the server indicators received from a temperature sensor 103 may indicate the current temperature of a component and the server indicators received from a task scheduler 104 and/or traffic switch(es) 105 may indicate the upcoming usage for the server, and the cooling control device 100 can determine the amount of cooling necessary to achieve and/or maintain the server (or given component of the server 101) at a target temperature.

In some embodiments, the source of the server indicator may affect the level of importance in determining the expected cooling demand. In such an embodiment, the temperature sensor(s) 103, the task scheduler 104, and the traffic switch(es) 105 may be ranked in importance, such that server indicators from one source are given more weight in determining the expected cooling demand. For example, the temperature of a component may be more of a factor in determining the expected cooling demand than the task information provided from a traffic switch 105.

Referring now to Block 320 of FIG. 3, embodiments of the method include adjusting a cooling amount provided by a cooling mechanism (e.g., a cooling mechanism device 102) based on the expected cooling demand of the at least one component. The cooling amount provided by the cooling mechanism (e.g., cooling mechanism device 102) may be expressed as a percentage of total cooling available. In various embodiments, the cooling mechanism device 102 has individual cooling components that are configured to target individual components of a server 101. As discussed above, the cooling mechanism device 102 may include air cooling mechanisms and/or liquid cooling mechanisms.

The adjustment to the cooling amount by the cooling mechanism can be executed before a given task begins execution. For example, in an instance in which the cooling control device 100 receives a server indicator from a task scheduler 104 or traffic switch(es) 105, the adjustment to the cooling amount can be determined before the server begins execution of the task. Proactive adjustment allows for the system to more effectively prepare for expected change in the temperature of a server. For example, in an instance in which a heavy GPU task is scheduled for the given server, the system discussed herein allows the cooling amount to be adjusted before the task begins, which results in less reactive and more efficient cooling (e.g., the cooling amount provided to the GPU can be increased to lower the temperature of the GPU before the task begins in anticipation of the heat to be generated as the task is executed).

Referring now to optional Block 330 of FIG. 3, the method may include monitoring a temperature of the at least one component during execution of the task. The system may actively monitor the temperature of the server (and/or server components) during execution to determine whether any adjustments to the cooling amount is necessary. The system may have a target temperature of the server and/or the individual server components. As such, the temperature of the server and/or components may be monitored to determine whether the temperature matches the target temperature (e.g., the temperature should match the target temperature in an instance in which the expected demand determined by the system matches the actual demand). In an instance which the temperature of the server and/or a component of the server differs from the target temperature, the cooling amount may be adjusted to move the temperature closer to the target temperature. Additionally or alternatively, the monitored temperature compared to the target temperature may be used to train the machine learning model, as discussed in reference to Block 340 below.

Referring now to optional Block 340 of FIG. 3, the method may include teaching a training set to determine the expected cooling demand via a machine learning model. The system may both initially train a machine learning model using historical data as a training set. For example, data relating to cooling amount and temperature of servers and server components during operation may be inputted into the machine learning model and used to train the machine learning model. The machine learning model can be trained using various techniques. Example data used for teaching a training set includes data collected by data center health software (e.g., a data center may have internal health logging software installed to monitor the data center).

Referring now to optional Block 350 of FIG. 3, the method may include monitoring the server during execution of the task and updating the training set based on the monitored task execution. The server and/or components may be monitored during or after the execution of the given task and the state of the server and/or components (e.g., the temperature) may be compared to the expected state of the server and/or components (e.g., the expected cooling demand). The training set may be updated to include data relating to the execution of the task (e.g., past component temperatures and information relating to previous tasks completed). As such, the machine learning model may be updated.

The present disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

As used herein, “machine learning models” may refer to programs (math and logic) that are configured to self-adjust and perform better as they are exposed to more data. To this extent, machine learning models are capable of adjusting their own parameters, given feedback on previous performance in making prediction about a dataset. The machine learning models may be trained via one or more training sets that include historical information that can be used to make such predictions. The machine learning model is a mathematical model generated by machine learning algorithms based on sample data, known as training data, to make predictions or decisions without being explicitly programmed to do so. The machine learning model represents what was learned by the machine learning algorithm and represents the rules, numbers, and any other algorithm-specific data structures required to for classification. Machine learning models contemplated, described, and/or used herein include supervised learning (e.g., using logistic regression, using back propagation neural networks, using random forests, decision trees, etc.), unsupervised learning (e.g., using an Apriori algorithm, using K-means clustering), semi-supervised learning, reinforcement learning (e.g., using a Q-learning algorithm, using temporal difference learning), and/or any other suitable machine learning model type. Various machine learning models may use time-based machine learning algorithms and/or time-based deep learning algorithms, such as recurrent neural networks, gated recurrent unit algorithms, long term short memory, and/or the like. Various machine learning models may use tabular algorithms, such as collaborative filtering, recommendation engines, k-nearest neighbors, principal component analysis, and/or the like. Various machine models may use search-based algorithms, such as similarity rankings (e.g., BM25). Each of these types of machine learning models can implement any suitable form of machine learning algorithm to produce the machine learning model.

Some embodiments of the present disclosure are described herein with reference to flowchart illustrations and/or block diagrams of apparatus and/or methods. It will be understood that each block included in the flowchart illustrations and/or block diagrams, and/or combinations of blocks included in the flowchart illustrations and/or block diagrams, may be implemented by one or more computer-executable program code portions. These one or more computer-executable program code portions may be provided to a processor of a general purpose computer, special purpose computer, and/or some other programmable data processing apparatus in order to produce a particular machine, such that the one or more computer-executable program code portions, which execute via the processor of the computer and/or other programmable data processing apparatus, create mechanisms for implementing the steps and/or functions represented by the flowchart(s) and/or block diagram block(s).

The one or more computer-executable program code portions may be stored in a transitory and/or non-transitory computer-readable medium (e.g., a memory) that may direct, instruct, and/or cause a computer and/or other programmable data processing apparatus to function in a particular manner, such that the computer-executable program code portions stored in the computer-readable medium produce an article of manufacture including instruction mechanisms which implement the steps and/or functions specified in the flowchart(s) and/or block diagram block(s).

The one or more computer-executable program code portions may also be loaded onto a computer and/or other programmable data processing apparatus to cause a series of operational steps to be performed on the computer and/or other programmable apparatus. In some embodiments, this produces a computer-implemented process such that the one or more computer-executable program code portions which execute on the computer and/or other programmable apparatus provide operational steps to implement the steps specified in the flowchart(s) and/or the functions specified in the block diagram block(s). Alternatively, computer-implemented steps may be combined with, and/or replaced with, operator- and/or human-implemented steps in order to carry out an embodiment of the present disclosure.

Although many embodiments of the present disclosure have just been described above, the present disclosure may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present disclosure described and/or contemplated herein may be included in any of the other embodiments of the present disclosure described and/or contemplated herein, and/or vice versa.

While certain exemplary embodiments have been described and shown in the accompanying drawings, it is to be understood that such embodiments are merely illustrative of and not restrictive on the broad disclosure, and that this disclosure not be limited to the specific constructions and arrangements shown and described, since various other changes, combinations, omissions, modifications and substitutions, in addition to those set forth in the above paragraphs, are possible. Those skilled in the art will appreciate that various adaptations, modifications, and combinations of the just described embodiments may be configured without departing from the scope and spirit of the disclosure. Therefore, it is to be understood that, within the scope of the appended claims, the disclosure may be practiced other than as specifically described herein.

Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method for controlling cooling in a server, the method comprising:
receiving one or more server indicators relating to a task to be executed by at least one component of the server;
determining, via a processor, an expected cooling demand for the at least one component based on the one or more server indicators; and
adjusting a cooling amount provided by a cooling mechanism based on the expected cooling demand of the at least one component.

2. The method of claim 1, wherein at least one of the one or more server indicators is received from a scheduler, wherein the scheduler indicates one or more upcoming tasks to be executed by the server.

3. The method of claim 2, wherein the at least one of the one or more server indicators received from the scheduler indicates an expected usage of at least one of the at least one component for the task.

4. The method of claim 1, wherein at least one of the one or more server indicators is received from a switch connected to the server, wherein the at least one of the one or more server indicators comprises information relating to traffic routing via the switch.

5. The method of claim 1, wherein at least one of the one or more server indicators is based on a temperature measured by a temperature sensor.

6. The method of claim 1, wherein at least two of the one or more server indicators are received from at least two of a scheduler, a switch, or a temperature sensor.

7. The method of claim 1, wherein the one or more server indicators comprise at least one server indicator received from a scheduler, at least one server indicator received from a switch, and at least one server indicator received from a temperature sensor, wherein each of the at least one server indicator received from the scheduler, the at least one server indicator received from the switch, and the at least one server indicator received from the temperature sensor is used to determine the expected cooling demand.

8. The method of claim 1, further comprising monitoring a temperature of the at least one component during execution of the task, wherein the temperature of the component during the execution is compared to a target temperature to determine whether the cooling amount was correct.

9. The method of claim 1, further comprising teaching a training set to determine the expected cooling demand via a machine learning model.

10. The method of claim 9, further comprising monitoring the server during execution of the task and updating the training set based on the monitored task execution.

11. A system for controlling cooling in a server, the system comprising:
a server of a data center comprising at least one component;
a cooling mechanism for providing a cooling amount to the server; and
a controller in communication with the server and the cooling mechanism, wherein the controller is configured to:
receive one or more server indicators relating to a task to be executed for at least one component of the server;
determine, via a processor, an expected cooling demand for the at least one component based on the one or more server indicators; and
adjust a cooling amount provided by the cooling mechanism based on the expected cooling demand of the at least one component.

12. The system of claim 11, wherein at least one of the one or more server indicators is received from a scheduler, wherein the scheduler indicates one or more upcoming tasks to be executed by the server.

13. The system of claim 12, wherein the at least one of the one or more server indicators received from the scheduler indicates an expected usage of at least one of the at least one component for the task.

14. The system of claim 11, further comprising a switch connected to the server, wherein at least one of the one or more server indicators is received from the switch connected to the server, wherein the at least one of the one or more server indicators comprises information relating to traffic routing via the switch.

15. The system of claim 11, wherein the cooling mechanism is at least one of a liquid cooling mechanism or an air cooling mechanism.

16. The system of claim 11, further comprising a temperature sensor positioned adjacent to the at least one component, wherein at least one of the one or more server indicators is based on a temperature measured by the temperature sensor.

17. The system of claim 11, wherein at least one of the one or more server indicators indicates a temperature of one or more servers adjacent to the server.

18. A computer program product for controlling cooling in a server, the computer program product comprising at least one non-transitory computer-readable medium having computer-readable program code portions embodied therein, the computer-readable program code portions comprising an executable portion configured to:
receive one or more server indicators relating to a task to be executed for at least one component of a server;
determine, based on the one or more server indicators, an expected cooling demand for the at least one component; and
adjust a cooling amount provided by a cooling mechanism based on the expected cooling demand of the at least one component.

19. The computer program product of claim 18, wherein at least one of the one or more server indicators is received from a scheduler, wherein the scheduler indicates one or more upcoming tasks to be executed by the server.

20. The computer program product of claim 19, wherein the at least one of the one or more server indicators received from the scheduler indicates an expected usage of at least one of the at least one component for the task.

21. The computer program product of claim 18, wherein at least one of the one or more server indicators is received from a switch connected to the server, wherein the at least one of the one or more server indicators comprises information relating to traffic routing via the switch.

22. The computer program product of claim 18, wherein at least one of the one or more server indicators is based on a temperature measured by a temperature sensor.

23. The computer program product of claim 18, further comprising an executable portion configured to monitor a temperature of the at least one component during execution of the task, wherein the temperature of the component during the execution is compared to a target temperature to determine whether the cooling amount was correct.

24. The computer program product of claim 18, further comprising an executable portion configured to teach a training set to determine the expected cooling demand via a machine learning model.

25. The computer program product of claim 18, further comprising an executable portion configured to monitor the server during execution of the task and updating a training set based on the monitored task execution.
